(19) United States
(12) Patent Application Publication
(10) Pub. No.: US 2024/0429355 A1
(43) Pub. Date: Dec. 26, 2024

(54) SEMICONDUCTOR LIGHT-EMITTING APPARATUS

(71) Applicant: NIKKISO CO., LTD., Tokyo (JP)

(72) Inventors: Izumi KIDA, Ishikawa (JP); Naoki SHIBATA, Ishikawa (JP); Tetsuhiko INAZU, Ishikawa (JP)

(21) Appl. No.: 18/750,407

(22) Filed: Jun. 21, 2024

(30) Foreign Application Priority Data
Jun. 21, 2023 (JP) 2023-101368

(51) Int. Cl. H01L 33/58; H01L 33/54

(52) U.S. Cl. CPC H01L 33/58; H01L 33/54

(57) ABSTRACT

A semiconductor light-emitting apparatus includes: a package substrate; a semiconductor light-emitting element flip-chip bonded on the package substrate; a frame body provided around the semiconductor light-emitting element on the package substrate; and a sealing member that covers an upper surface of the semiconductor light-emitting element on the package substrate, covers an upper surface of the frame body, and has translucency at an emission wavelength of the semiconductor light-emitting element. The upper surface of the semiconductor light-emitting element has a plurality of corner portions, and a distance from each of the plurality of corner portions to the frame body is smaller than a width of the upper surface of the frame body.

### RELATED APPLICATION

Priority is claimed to Japanese Patent Application No. 2023-101368, filed on Jun. 21, 2023, the entire content of which is incorporated herein by reference.

### BACKGROUND

### 1. Technical Field

The present disclosure relates to a semiconductor light-emitting apparatus.

### 2. Description of the Related Art

A semiconductor light-emitting apparatus in which a semiconductor light-emitting element bonded on a package substrate is sealed by a resin is known. For example, a technology for improving light extraction efficiency by forming the sealing resin in an upward convex dome shape has been proposed (see, for example, JP2017-59754).

To form a sealing member in a dome shape, it is necessary to increase the thickness of the sealing member located above the semiconductor light-emitting element. Increasing the amount of the sealing member filling the dome increases a distortion caused by a difference in the material between the sealing member and the package substrate with the result that the sealing member is easily exfoliated or cracked.

### SUMMARY

The present disclosure addresses the issue described above, and a purpose thereof is to provide a technology for improving the light extraction efficiency and the reliability of a semiconductor light-emitting apparatus.

A semiconductor light-emitting apparatus according to an embodiment of the present disclosure includes: a package substrate; a semiconductor light-emitting element flip-chip bonded on the package substrate; a frame body provided around the semiconductor light-emitting element on the package substrate; and a sealing member that covers an upper surface of the semiconductor light-emitting element on the package substrate, covers an upper surface of the frame body, and has translucency at an emission wavelength of the semiconductor light-emitting element. The upper surface of the semiconductor light-emitting element has a plurality of corner portions, and a distance from each of the plurality of corner portions to the frame body is smaller than a width of the upper surface of the frame body.

### BRIEF DESCRIPTION OF THE DRAWINGS

FIG. 1 is a cross-sectional view schematically showing a configuration of a semiconductor light-emitting apparatus according to the first embodiment.

FIG. 2 is a top view schematically showing a configuration of a semiconductor light-emitting apparatus according to the first embodiment.

FIG. 3 is a cross-sectional view schematically showing a configuration of a semiconductor light-emitting apparatus according to the second embodiment.

FIG. 4 is a top view schematically showing a configuration of a semiconductor light-emitting apparatus according to the third embodiment.

FIG. 5 is a top view schematically showing a configuration of a semiconductor light-emitting apparatus according to the fourth embodiment.

### DETAILED DESCRIPTION

The invention will now be described by reference to the preferred embodiments. This does not intend to limit the scope of the present invention, but to exemplify the invention.

According to the present disclosure, the light extraction efficiency and the reliability of a semiconductor light-emitting apparatus can be improved.

A description will be given of an embodiment to practice the present disclosure with reference to the drawings. The numerals are used in the description to denote the same elements and a duplicate description is omitted as appropriate. To facilitate the understanding, the relative dimensions of the constituting elements in the drawings do not necessarily mirror the relative dimensions in the light-emitting element.

### First Embodiment

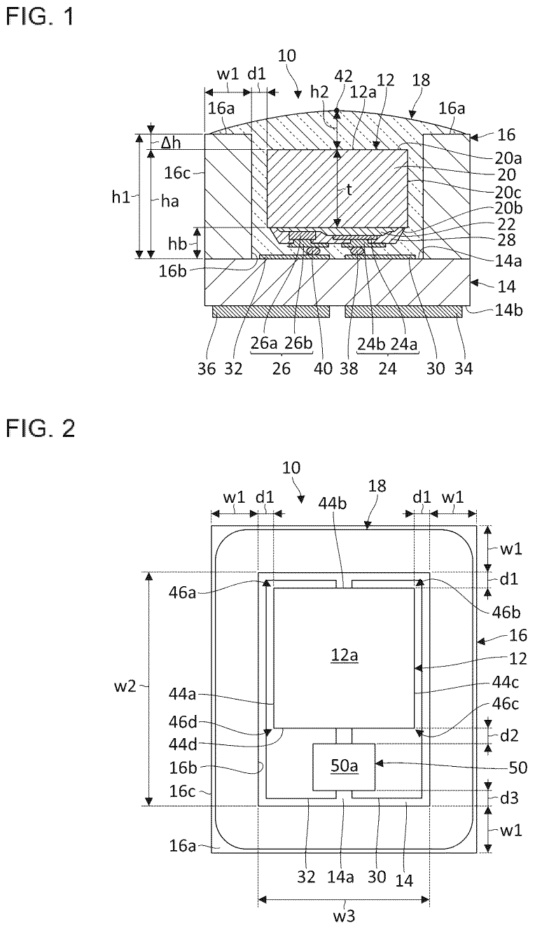

FIG. 1 is a cross-sectional view schematically showing a configuration of a semiconductor light-emitting apparatus 10 according to the first embodiment. The semiconductor light-emitting apparatus 10 includes a semiconductor light-emitting element 12, a package substrate 14, a frame body 16, and a sealing member 18.

The semiconductor light-emitting element 12 is a semiconductor light-emitting element configured to emit ultraviolet light having a central wavelength λ of approximately equal to or less than 360 nm. To output ultraviolet light having such a wavelength, an aluminum gallium nitride (AlGaN)-based semiconductor material having a band gap approximately equal to or more than 3.4 eV is used. In the embodiment, a deep ultraviolet-light emitting diode (DUV-LED) chip configured to emit deep ultraviolet light having a central wavelength A of about 240 nm to 320 nm will be highlighted.

The semiconductor light-emitting element 12 includes a translucent substrate 20, a semiconductor layer 22, an anode electrode 24, a cathode electrode 26, and a protective layer 28.

The translucent substrate 20 is made of a material having translucency for the ultraviolet light emitted by the semiconductor light-emitting element 12. The light emitted by the semiconductor layer 22 is output outside the semiconductor light-emitting element 12 from the translucent substrate 20. The translucent substrate 20 is made of, for example, sapphire (Al₂O₃). The translucent substrate 20 includes an upper surface 20a, a lower surface 20b, and a side surface 20c. The upper surface 20a and the lower surface 20b has, for example, a rectangular shape. The size of the upper surface 20a and the lower surface 20b is not limited to a particular size. For example, the upper surface 20a and the lower surface 20b are 1 mm by 1 mm in size. The thickness t of the translucent substrate 20 from the upper surface 20a to the lower surface 20b is, for example, equal to or more than 100 μm, equal to or more than 200 μm, or equal to or more than 300 μm and is, for example, equal to or less than 1000 μm, equal to or less than 700 μm, or equal to or less than 500 μm.

The semiconductor layer 22 is provided below the translucent substrate 20 and is provided on the lower surface 20b of the translucent substrate 20. The semiconductor layer 22 includes, for example, an n-type semiconductor layer, an active layer, and a p-type semiconductor layer. The semiconductor layer 22 is made of an AlGaN-based semiconductor material. The AlGaN-based semiconductor material can be represented by a composition In_{1-x-y}AlₓGa_{y}N (0<x+y≤1, 0<x<1, 0<y<1). The semiconductor layer 22 is covered by the protective layer 28.

The anode electrode 24 includes a first contact electrode 24a and a first pad electrode 24b. The first contact electrode 24a is an internal electrode in contact with the semiconductor layer 22 and is in contact with the p-type semiconductor layer included in the semiconductor layer 22. The first contact electrode 24a is comprised of, for example, a metal layer made of Rh, etc. The first contact electrode 24a is covered by the protective layer 28. The first pad electrode 24b is an external electrode exposed outside the protective layer 28 and is electrically connected to the first contact electrode 24a via an opening provided in the protective layer 28. The first pad electrode 24b is comprised of a metal layer made of Ni/Au, etc.

The cathode electrode 26 includes a second contact electrode 26a and a second pad electrode 26b. The second contact electrode 26a is an internal electrode in contact with the semiconductor layer 22 and is in contact with the n-type semiconductor layer included in the semiconductor layer 22. The second contact electrode 26a is comprised of, for example, a metal layer made of Ti/Al, etc. The second contact electrode 26a is covered by the protective layer 28. The second pad electrode 26b is an external electrode exposed outside the protective layer 28 and is electrically connected to the second contact electrode 26a via an opening provided in the protective layer 28. The second pad electrode 26b is comprised of a metal layer made of Ni/Au, etc.

The protective layer 28 covers the semiconductor layer 22, the first contact electrode 24a, and the second contact electrode 26a. The protective layer 28 is made of a dielectric material such as oxide and nitride and is made of, for example, silicon oxide (SiO₂), aluminum oxide (Al₂O₃), silicon nitride (SiN), etc. The protective layer 28 may be comprised of a stack of a plurality of protective layers made of different materials.

The package substrate 14 has a flat plate shape, and has a bonding surface 14a and a back surface 14b. The package substrate 14 includes a first bonding electrode 30 and a second bonding electrode 32 provided on the bonding surface 14a. The package substrate 14 includes a first mounting electrode 34 and a second mounting electrode 36 provided on the back surface 14b. The first bonding electrode 30 is electrically connected to the first mounting electrode 34 inside the package substrate 14. The second bonding electrode 32 is electrically connected to the second mounting electrode 36 inside the package substrate 14. The package substrate 14 is made of, for example, an inorganic material, and is made of a ceramic material such as alumina (Al₂O₃), aluminum nitride (AlN), silicon nitride (SiN), and silicon carbide (SiC).

The semiconductor light-emitting element 12 is flip-chip bonded on the package substrate 14. The semiconductor light-emitting element 12 is bonded to the first bonding electrode 30 and the second bonding electrode 32. The semiconductor light-emitting element 12 is bonded to the package substrate 14 via a first bonding part 38 and a second bonding part 40. The first bonding part 38 is provided between the anode electrode 24 (the first pad electrode 24b) and the first bonding electrode 30 to connect the anode electrode 24 and the first bonding electrode 30 electrically. The second bonding part 40 is provided between the cathode electrode 26 (the second pad electrode 26b) and the second bonding electrode 32 to connect the cathode electrode 26 and the second bonding electrode 32 electrically.

The first bonding part 38 and the second bonding part 40 are, for example, stud bumps. The first bonding part 38 and the second bonding part 40 are formed by, for example, melting the tip of a metal wire made of Au, etc. to form a ball and pressing the ball against the first bonding electrode 30 and the second bonding electrode 32, respectively. The first bonding part 38 and the second bonding part 40 formed on the first bonding electrode 30 and the second bonding electrode 32 are respectively bonded to the anode electrode 24 (the first pad electrode 24b) and the cathode electrode 26 (the second pad electrode 26b) by, for example, ultrasonic bonding.

In a state where the semiconductor light-emitting element 12 is bonded to the package substrate 14, the height hb from the package substrate 14 (the bonding surface 14a) to the lower surface 20b of the translucent substrate 20 is, for example, smaller than the thickness t of the translucent substrate 20 and is, for example, smaller than half t/2 the thickness of the translucent substrate 20. The height hb from the package substrate 14 to the lower surface 20b of the translucent substrate 20 is, for example, equal to or less than 200 μm, equal to or less than 100 μm, equal to or less than 50 μm, or equal to or less than 30 μm. The height hb from the package substrate 14 to the lower surface 20b of the translucent substrate 20 is, for example, equal to or more than 10 μm, equal to or more than 15 μm, equal to or more than 20 μm, or equal to or more than 25 μm.

In a state where the semiconductor light-emitting element 12 is bonded to the package substrate 14, the height ha from the package substrate 14 (the bonding surface 14a) to the upper surface 12a of the semiconductor light-emitting element 12 (the upper surface 20a of the translucent substrate 20) is, for example, equal to or more than 100 μm, equal to or more than 200 μm, equal to or more than 300 μm, or equal to or more than 400 μm. The height ha from the package substrate 14 to the upper surface 12a of the semiconductor light-emitting element 12 is, for example, equal to or less than 1000 μm, equal to or less than 700 μm, equal to or less than 600 μm, or equal to or less than 500 μm.

The frame body 16 is provided around the semiconductor light-emitting element 12 on the package substrate 14. The frame body 16 is provided, for example, along the outer circumference of the package substrate 14 and over the entire circumference of the package substrate 14. The frame body 16 may be provided away from the outer circumference of the package substrate 14 or may be provided at a position displaced inward from the outer circumference of the package substrate 14. The frame body 16 is made of, for example, the same material as that of the package substrate 14, and is integrally molded with the package substrate 14. The frame body 16 may be made of a material different from that of the package substrate 14. The frame body 16 may be molded as a body separate from the package substrate 14, or may be bonded to the bonding surface 14a of the package substrate 14 by any bonding material.

The frame body 16 has an upper surface 16a. The upper surface 16a of the frame body 16 is, for example, a flat surface. The height h1 of the upper surface 16a of the frame body 16 is equal to or more than the height ha of the upper surface 12a of the semiconductor light-emitting element 12 (the upper surface 20a of the translucent substrate 20). The height h1 of the upper surface 16a of the frame body 16 is, for example, equal to or more than 200 μm, equal to or more than 300 μm, equal to or more than 400 μm, or equal to or more than 500 μm. The height h1 of the upper surface 16a of the frame body 16 is, for example, equal to or less than 1500 μm, equal to or less than 1200 μm, equal to or less than 1000 μm, or equal to or less than 800 μm. The difference Δh (=h1−ha) between the height h1 of the upper surface 16a of the frame body 16 and the height ha of the upper surface 12a of the semiconductor light-emitting element 12 is, for example, equal to or more than 50 μm, equal to or more than 100 μm, or equal to or more than 200 μm and is, for example, equal to or less than 500 μm, equal to or less than 400 μm, or equal to or less than 300 μm.

The frame body 16 has an inner circumferential surface 16b and an outer circumferential surface 16c. The width w1 of the upper surface 16a of the frame body 16 (for example, the width w1 from the inner circumferential surface 16b to the outer circumferential surface 16c) is, for example, equal to or more than 100 μm, equal to or more than 200 μm, equal to or more than 300 μm, or equal to or more than 400 μm. The width w1 of the upper surface 16a of the frame body 16 is, for example, equal to or less than 1000 μm, equal to or less than 800 μm, equal to or less than 700 μm, or equal to or less than 600 μm. The distance d1 from the semiconductor light-emitting element 12 (the side surface 20c of the translucent substrate 20) to the frame body 16 (the inner circumferential surface 16b) is smaller than the width w1 of the frame body 16. The distance d1 from the semiconductor light-emitting element 12 to the frame body 16 is, for example, equal to or less than 300 μm, equal to or less than 200 μm, equal to or less than 150 μm, or equal to or less than 100 μm. The distance d1 from the semiconductor light-emitting element 12 to the frame body 16 is, for example, equal to or more than 10 μm, equal to or more than 50 μm, equal to or more than 100 μm, or equal to or more than 150 μm.

The sealing member 18 covers the semiconductor light-emitting element 12 on the package substrate 14. The sealing member 18 fills, for example, an area inward of the frame body 16. The sealing member 18 is in contact with the bonding surface 14a of the package substrate 14 and is in contact with the first bonding electrode 30 and the second bonding electrode 32. The sealing member 18 is in contact with the side surface 20c and the upper surface 20a of the translucent substrate 20. The sealing member 18 covers the upper surface 16a of the frame body 16. The sealing member 18 is made of a material having translucency at the emission wavelength of the semiconductor light-emitting element 12. The sealing member 18 has an internal transmittance of equal to or more than 508, and, preferably equal to or more than 70%, equal to or more than 80%, or equal to or more than 90% at the peak emission wavelength of the semiconductor light-emitting element 12. The sealing member 18 is made of a material having a lower refractive index than the translucent substrate 20. The sealing member 18 is made of, for example, a silicone resin or a fluororesin. The sealing member 18 may be made of an inorganic material such as quartz or a glass material instead of a resin. The sealing member 18 is configured not to contain, for example, a phosphor.

The sealing member 18 has, for example, a lens shape or a dome shape that is convex upward. An apex portion 42 of the sealing member 18 is, for example, located above the semiconductor light-emitting element 12 bonded to the package substrate 14. The sealing member 18 is formed to cover the entirety of the upper surface 12a of the semiconductor light-emitting element 12. The height h2 from the upper surface 12a of the semiconductor light-emitting element 12 to the apex portion 42 of the sealing member 18 is, for example, equal to or more than 100 μm, equal to or more than 200 μm, or equal to or more than 300 μm. The height h2 from the upper surface 12a of the semiconductor light-emitting element 12 to the apex portion 42 of the sealing member 18 is, for example, equal to or less than 1000 μm, equal to or less than 800 μm, or equal to or less than 500 μm. The height h2 from the upper surface 12a of the semiconductor light-emitting element 12 to the apex portion 42 of the sealing member 18 is, for example, smaller than the height h1 of the frame body 16. The height h2 from the upper surface 12a of the semiconductor light-emitting element 12 to the apex portion 42 of the sealing member 18 is, for example, smaller than the height ha of the semiconductor light-emitting element 12.

FIG. 2 is a top view schematically showing a configuration of the semiconductor light-emitting apparatus 10 according to the first embodiment. The semiconductor light-emitting apparatus 10 further includes a protective element 50. The protective element 50 is a diode for protecting the semiconductor light-emitting element 12 from a surge current or static electricity and is, for example, a Zener diode. The protective element 50 is bonded to the bonding surface 14a of the package substrate 14. The protective element 50 is bonded to the first bonding electrode 30 and the second bonding electrode 32 and is connected in parallel with the semiconductor light-emitting element 12. An upper surface 50a of the protective element 50 is covered by the sealing member 18.

The frame body 16 is configured such that the inner circumferential surface 16b and the outer circumferential surface 16c are rectangular. The frame body 16 has a rectangular shape having a relatively large size in the vertical direction in which the semiconductor light-emitting element 12 and the protective element 50 are arranged and a relatively small lateral size. The vertical width w2 inward of the frame body 16 is larger than the lateral width w3 inward of the frame body 16. The vertical width w2 inward of the frame body 16 is, for example, equal to or more than 1.1 times and equal to or less than twice the lateral width w3 inward of the frame body 16.

The upper surface 12a of the semiconductor light-emitting element 12 has a plurality of sides 44a, 44b, 44c, 44d and a plurality of corner portions 46a, 46b, 46c, 46d. In the example of FIG. 2, the upper surface 12a of the semiconductor light-emitting element 12 is rectangular and has four sides 44a-44d and four corner portions 46a-46d. The upper surface 12a of the semiconductor light-emitting element 12 may not be rectangular and may have a polygonal shape such as a triangle, hexagon, or octagon shape different from a quadrilateral shape.

In the semiconductor light-emitting element 12, each of the plurality of corner portions 46a-46d is arranged in close proximity to the inner circumferential surface 16b of the frame body 16. Each of the three sides 44a-44c of the semiconductor light-emitting element 12 is arranged in close proximity to the inner circumferential surface 16b. The distance d1 from each of the plurality of corner portions 46a-46d to the frame body 16 is, for example, smaller than the width w1 of the frame body 16. The distance d1 from each of the plurality of corner portions 46a-46d to the frame body 16 is, for example, equal to or less than 300 μm, equal to or less than 200 μm, equal to or less than 150 μm, or equal to or less than 100 μm. The distance d1 from each of the plurality of corner portions 46a-46d to the frame body 16 is, for example, equal to or more than 10 μm, equal to or more than 50 μm, equal to or more than 100 μm, or equal to or more than 150 μm.

The protective element 50 is arranged in close proximity to one side 44d of the semiconductor light-emitting element 12. The distance d2 from the semiconductor light-emitting element 12 to the protective element 50 is, for example, smaller than the width w1 of the frame body 16. The distance d2 from the semiconductor light-emitting element 12 to the protective element 50 is, for example, about the same as the distance d1 from the semiconductor light-emitting element 12 to the frame body 16. The distance d2 from the semiconductor light-emitting element 12 to the protective element 50 is, for example, equal to or less than 300 μm, equal to or less than 200 μm, equal to or less than 150 μm, or equal to or less than 100 μm. The distance d2 from the semiconductor light-emitting element 12 to the protective element 50 is, for example, equal to or more than 10 μm, equal to or more than 50 μm, equal to or more than 100 μm, or equal to or more than 150 μm.

The protective element 50 is arranged in close proximity to the frame body 16. The distance d3 from the protective element 50 to the frame body 16 is, for example, smaller than the width w1 of the frame body 16. The distance d3 from the protective element 50 to the frame body 16 is, for example, about the same as the distance d1 from the semiconductor light-emitting element 12 to the frame body 16 or the distance d2 from the semiconductor light-emitting element 12 to the protective element 50. The distance d3 from the protective element 50 to the frame body 16 is, for example, equal to or less than 300 μm, equal to or less than 200 μm, equal to or less than 150 μm, or equal to or less than 100 μm. The distance d3 from the protective element 50 to the frame body 16 is, for example, equal to or more than 10 μm, equal to or more than 50 μm, equal to or more than 100 μm, or equal to or more than 150 μm.

According to this embodiment, the amount of the sealing member 18 provided between the semiconductor light-emitting element 12 and the frame body 16 can be reduced by reducing the distance d1 from the semiconductor light-emitting element 12 to the frame body 16. In particular, the amount of the sealing member 18 provided between each of the plurality of corner portions 46a-46d of the semiconductor light-emitting element 12 and the frame body 16 can be reduced. As a result, the stress applied to the sealing member 18 due to the difference in the material between the sealing member 18 and the frame body 16 can be reduced to suppress the occurrence of exfoliation and cracks of the sealing member 18, and the reliability of the semiconductor light-emitting apparatus 10 can be improved.

According to this embodiment, the amount of the sealing member 18 provided around the protective element 50 can be reduced by reducing the distance d2 from the semiconductor light-emitting element 12 to the protective element 50 and reducing the distance d3 from the protective element 50 to the frame body 16. As a result, the stress applied to the sealing member 18 due to the difference in the material between the sealing member 18 and the frame body 16 can be reduced to suppress the occurrence of exfoliation and cracks of the sealing member 18, and the reliability of the semiconductor light-emitting apparatus 10 can be improved.

In the plan view of FIG. 2, the area S occupying the space inward of the frame body 16 (the inner circumferential surface 16b of the frame body 16) may be equal to or less than twice the total area (P+Q) of the area P occupying the upper surface 12a of the semiconductor light-emitting element 12 and the area Q occupying the upper surface 50a of the protective element 50 (i.e., S≤2×[P+Q]). In other words, the area (S−P−Q) of a portion of the space inward of the frame body 16 outside the semiconductor light-emitting element 12 and the protective element 50 may be smaller than the total area (P+Q) of the semiconductor light-emitting element 12 and the protective element 50. In this case, the amount of the sealing member 18 provided around the semiconductor light-emitting element 12 and the protective element 50 (for example, lateral to the semiconductor light-emitting element 12 and the protective element 50) can be reduced with respect to the amount of the sealing member 18 covering the upper surface 12a of the semiconductor light-emitting element 12 and the upper surface 50a of the protective element 50. As a result, the stress applied to the sealing member 18 due to the difference in the material between the sealing member 18 and the frame body 16 can be reduced to suppress the occurrence of exfoliation and cracks of the sealing member 18, and the reliability of the semiconductor light-emitting apparatus 10 can be improved.

In the plan view of FIG. 2, the area S occupying the space inward of the frame body 16 (the inner circumferential surface 16b of the frame body 16) may be equal to or less than twice the area P occupying the upper surface 12a of the semiconductor light-emitting element 12 (i.e., S≤2×P). In other words, the area (S−P) of a portion of the space inward of the frame body 16 outside the semiconductor light-emitting element 12 may be smaller than the area P of the semiconductor light-emitting element 12. In this case, the amount of the sealing member 18 provided around the semiconductor light-emitting element 12 (for example, lateral to the semiconductor light-emitting element 12) can be reduced with respect to the amount of the sealing member 18 covering the upper surface 12a of the semiconductor light-emitting element 12. As a result, the stress applied to the sealing member 18 due to the difference in the material between the sealing member 18 and the frame body 16 can be reduced to suppress the occurrence of exfoliation and cracks of the sealing member 18, and the reliability of the semiconductor light-emitting apparatus 10 can be improved.

According to this embodiment, the sealing member 18 is provided to cover the upper surface 16a of the frame body 16 so that the quality of sealing of the semiconductor light-emitting element 12 by the sealing member 18 can be improved even when the distance d1 from the semiconductor light-emitting element 12 to the frame body 16 is configured to be small. In particular, the width w1 of the upper surface 16a of the frame body 16 is larger than the distance d1 from the semiconductor light-emitting element 12 to the frame body 16 so that the sealing member 18 covering the upper surface 16a of the frame body 16 can increase the quality of sealing. As a result, the reliability of the semiconductor light-emitting apparatus 10 can be improved.

### Second Embodiment

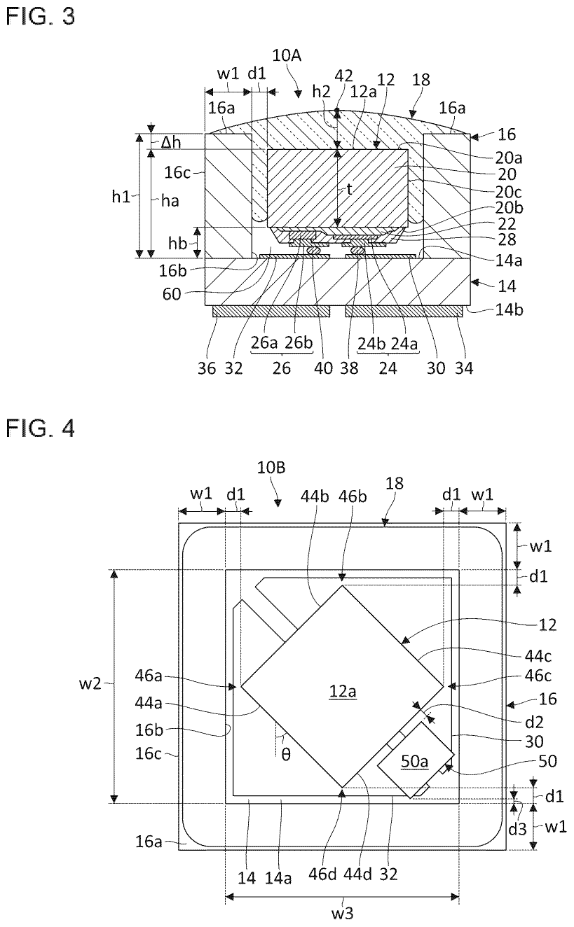

FIG. 3 is a cross-sectional view schematically showing a configuration of a semiconductor light-emitting apparatus 10A according to the second embodiment. The semiconductor light-emitting apparatus 10A differs from the first embodiment described above in that a gap 60 is provided between the package substrate 14 and the sealing member 18. The following description of the second embodiment highlights the difference from the first embodiment. A description of common features is omitted as appropriate.

The semiconductor light-emitting apparatus 10A includes a semiconductor light-emitting element 12, a package substrate 14, a frame body 16, and a sealing member 18. The semiconductor light-emitting apparatus 10A may further include the protective element 50 shown in FIG. 2. The semiconductor light-emitting element 12, the package substrate 14, the frame body 16, and the protective element 50 can be configured in the same manner as in the first embodiment.

The sealing member 18 can be configured in the same manner as in the first embodiment, except that the gap 60 is provided between the sealing member 18 and the package substrate 14. The sealing member 18 is, for example, provided in isolation from the package substrate 14 and is not in contact with the bonding surface 14a of the package substrate 14. The sealing member 18 may not be in contact with the first bonding electrode 30 and the second bonding electrode 32. The sealing member 18 may be partially in contact with the package substrate 14. For example, at least one of the bonding surface 14a of the package substrate 14, the first bonding electrode 30, or the second bonding electrode 32 may have a portion in contact with the sealing member 18 and a portion not in contact with the sealing member 18.

The sealing member 18 may be partially in contact with the semiconductor light-emitting element 12. The sealing member 18 may, for example, not be in contact with the protective layer 28. The sealing member 18 may be in contact with the entire side surface 20c of the translucent substrate 20 or may be in contact with only a portion of the side surface 20c of the translucent substrate 20. That is, the side surface 20c of the translucent substrate 20 may have a portion in contact with the sealing member 18 and a portion not in contact with the sealing member 18. The sealing member 18 is in contact with the entire upper surface 20a of the translucent substrate 20.

The sealing member 18 may be partially in contact with the frame body 16. The sealing member 18 may be in contact with, for example, only a portion of the inner circumferential surface 16b of the frame body 16. That is, the inner circumferential surface 16b of the frame body 16 may have a portion in contact with the sealing member 18 and a portion not in contact with the sealing member 18. The sealing member 18 may be in contact with substantially the entire upper surface 16a of the frame body 16 or may be in contact with equal to or more than 70%, equal to or more than 80%, or equal to or more than 90% of the area of the upper surface 16a of the frame body 16.

According to this embodiment, the stress applied to the sealing member 18 due to the difference in the material between the package substrate 14 and the sealing member 18 can be reduced by providing the sealing member 18 in isolation from the package substrate 14. As a result, the occurrence of exfoliation and cracks of the sealing member 18 can be suppressed, and the reliability of the semiconductor light-emitting apparatus 10A can be improved.

According to this embodiment, the area of contact between the sealing member 18 and the inner circumferential surface 16b of the frame body 16 is reduced so that the stress applied to the sealing member 18 due to the difference in the material between the frame body 16 and the sealing member 18 can be reduced. As a result, the occurrence of exfoliation and cracks of the sealing member 18 can be suppressed, and the reliability of the semiconductor light-emitting apparatus 10A can be improved.

### Third Embodiment

FIG. 4 is a top view schematically showing a configuration of a semiconductor light-emitting apparatus 10B according to the third embodiment. The semiconductor light-emitting apparatus 10B differs from the first embodiment described above in that the semiconductor light-emitting element 12 and the protective element 50 are arranged at an angle with respect to the package substrate 14 and the frame body 16. The following description of the third embodiment highlights the difference from the first embodiment. A description of common features is omitted as appropriate.

The semiconductor light-emitting apparatus 10B includes a semiconductor light-emitting element 12, a package substrate 14, a frame body 16, a sealing member 18, and a protective element 50. The semiconductor light-emitting element 12 and the protective element 50 can be configured in the same manner as in the first embodiment.

The package substrate 14 and the frame body 16 are configured to be square in shape and are configured such that the vertical and lateral sizes are about the same. The inner circumferential surface 16b and the outer circumferential surface 16c of the frame body 16 are configured to be square in shape and are configured such that the vertical and lateral sizes are about the same. The vertical width w2 inward of the frame body 16 is, for example, equal to or more than 0.9 times and equal to or less than 1.1 times the lateral width w3 inward of the frame body 16. The package substrate 14 and the frame body 16 may be configured to be rectangular in shape.

The semiconductor light-emitting element 12 is arranged inward of the frame body 16 in an orientation rotated by a predetermined angle θ with respect to the package substrate 14 and the frame body 16. Each of the plurality of sides 44a-44d of the semiconductor light-emitting element 12 is arranged to have a predetermined angle θ with respect to the inner circumferential surface 16b of the frame body 16. The predetermined angle θ is, for example, equal to or more than 10 degrees and equal to or less than 80 degrees, and is, for example, equal to or more than 30 degrees and equal to or less than 60 degrees. In the example shown in FIG. 4, the predetermined angle θ is 45 degrees.

In the semiconductor light-emitting element 12, each of the plurality of corner portions 46a-46d is arranged in close proximity to the inner circumferential surface 16b of the frame body 16. The distance d1 from each of the plurality of corner portions 46a-46d to the frame body 16 is, for example, smaller than the width w1 of the frame body 16. The distance d1 from each of the plurality of corner portions 46a-46d to the frame body 16 is, for example, equal to or less than 300 μm, equal to or less than 200 μm, equal to or less than 150 μm, or equal to or less than 100 μm. The distance d1 from each of the plurality of corner portions 46a-46d to the frame body 16 is, for example, equal to or more than 10 μm, equal to or more than 50 μm, equal to or more than 100 μm, or equal to or more than 150 μm.

Like the semiconductor light-emitting element 12, the protective element 50 is arranged inward of the frame body 16 in an orientation rotated by a predetermined angle θ with respect to the package substrate 14 and the frame body 16. The protective element 50 is arranged in close proximity to one side 44d of the semiconductor light-emitting element 12. The distance d2 from the semiconductor light-emitting element 12 to the protective element 50 is, for example, smaller than the width w1 of the frame body 16. The distance d2 from the semiconductor light-emitting element 12 to the protective element 50 is, for example, about the same as the distance d1 from the semiconductor light-emitting element 12 to the frame body 16. The distance d2 from the semiconductor light-emitting element 12 to the protective element 50 is, for example, equal to or less than 300 μm, equal to or less than 200 μm, equal to or less than 150 μm, or equal to or less than 100 μm. The distance d2 from the semiconductor light-emitting element 12 to the protective element 50 is, for example, equal to or more than 10 μm, equal to or more than 50 μm, equal to or more than 100 μm, or equal to or more than 150 μm.

The protective element 50 is arranged in close proximity to the frame body 16. The distance d3 from the protective element 50 to the frame body 16 is, for example, smaller than the width w1 of the frame body 16. The distance d3 from the protective element 50 to the frame body 16 is, for example, about the same as the distance d1 from the semiconductor light-emitting element 12 to the frame body 16 or the distance d2 from the semiconductor light-emitting element 12 to the protective element 50. The distance d3 from the protective element 50 to the frame body 16 is, for example, equal to or less than 300 μm, equal to or less than 200 μm, equal to or less than 150 μm, or equal to or less than 100 μm. The distance d3 from the protective element 50 to the frame body 16 is, for example, equal to or more than 10 μm, equal to or more than 50 μm, equal to or more than 100 μm, or equal to or more than 150 μm.

According to this embodiment, too, the amount of the sealing member 18 provided between the semiconductor light-emitting element 12 and the frame body 16 can be reduced by reducing the distance d1 from the semiconductor light-emitting element 12 to the frame body 16. In particular, the amount of the sealing member 18 provided between each of the plurality of corner portions 46a-46d of the semiconductor light-emitting element 12 and the frame body 16 can be reduced. As a result, the stress applied to the sealing member 18 due to the difference in the material between the sealing member 18 and the frame body 16 can be reduced to suppress the occurrence of exfoliation and cracks of the sealing member 18, and the reliability of the semiconductor light-emitting apparatus 10 can be improved.

According to this embodiment, too, the amount of the sealing member 18 provided around the protective element 50 can be reduced by reducing the distance d2 from the semiconductor light-emitting element 12 to the protective element 50 and reducing the distance d3 from the protective element 50 to the frame body 16. As a result, the stress applied to the sealing member 18 due to the difference in the material between the sealing member 18 and the frame body 16 can be reduced to suppress the occurrence of exfoliation and cracks of the sealing member 18, and the reliability of the semiconductor light-emitting apparatus 10 can be improved.

### Fourth Embodiment

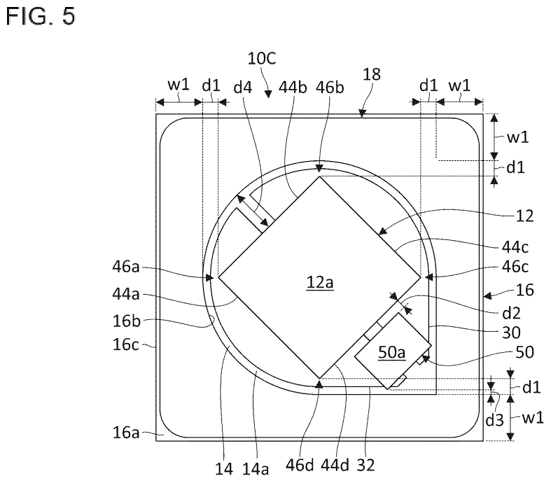

FIG. 5 is a top view schematically showing a configuration of a semiconductor light-emitting apparatus 10C according to the fourth embodiment. The semiconductor light-emitting apparatus 10C differs from the third embodiment in that the inner circumferential surface 16b of the frame body 16 is formed to extend in an arc shape rather than a rectangular shape and is otherwise similar to the third embodiment.

According to this embodiment, the distance d4 from each of the three sides 44a-44c of the upper surface 12a of the semiconductor light-emitting element 12 to the frame body 16 can be reduced, and the amount of the sealing member 18 provided inward of the frame body 16 can be reduced. As a result, the stress applied to the sealing member 18 due to the difference in the material between the sealing member 18 and the frame body 16 can be reduced to suppress the occurrence of exfoliation and cracks of the sealing member 18, and the reliability of the semiconductor light-emitting apparatus 10 can be improved.

Given above is a description of the present disclosure based on the embodiment. The present disclosure is not restricted by the embodiment described above, and it will be understood by those skilled in the art that various design changes are possible and various modifications are possible and that such modifications are also within the scope of the present disclosure.

Some aspects of the present disclosure will be described.

The first aspect of the present disclosure relates to a semiconductor light-emitting apparatus including: a package substrate; a semiconductor light-emitting element flip-chip bonded on the package substrate; a frame body provided around the semiconductor light-emitting element on the package substrate; and a sealing member that covers an upper surface of the semiconductor light-emitting element on the package substrate, covers an upper surface of the frame body, and has translucency at an emission wavelength of the semiconductor light-emitting element, wherein the upper surface of the semiconductor light-emitting element has a plurality of corner portions, and a distance from each of the plurality of corner portions to the frame body is smaller than a width of the upper surface of the frame body. According to the first aspect, the amount of the sealing member provided between the semiconductor light-emitting element and the frame can be reduced by reducing the distance from the corner portion of the semiconductor light-emitting element to the frame body. As a result, the stress applied to the sealing member due to the difference in the material between the sealing member and the frame body can be reduced, and the occurrence of exfoliation and cracks of the sealing member can be suppressed. The quality of sealing by the sealing member can be improved by configuring the width of the upper surface of the frame body covered by the sealing member to be large. This improves the reliability of the semiconductor light-emitting apparatus.

The second aspect of the present disclosure relates to the semiconductor light-emitting apparatus according to the first aspect, wherein, in a plan view of the upper surface of the semiconductor light-emitting apparatus, an area occupying a space inward of the frame body is equal to or less than twice an area occupying the upper surface of the semiconductor light-emitting element. According to the second aspect, the amount of the sealing member provided lateral to the semiconductor light-emitting element can be reduced with respect to the amount of the sealing member covering the upper surface of the semiconductor light-emitting element. As a result, the stress applied to the sealing member due to the difference in the material between the sealing member and the frame body can be reduced to suppress the occurrence of exfoliation and cracks of the sealing member, and the reliability of the semiconductor light-emitting apparatus can be improved.

The third aspect of the present disclosure relates to the semiconductor light-emitting apparatus according to the first aspect, further including: a protective element bonded on the package substrate and covered by the sealing member, wherein, in a plan view of the upper surface of the semiconductor light-emitting apparatus, an area occupying a space inward of the frame body is equal to or less than twice a total area of the upper surface of the semiconductor light-emitting element and an upper surface of the protective element. According to the third aspect, the amount of the sealing member provided lateral to the semiconductor light-emitting element and the protective element can be reduced with respect to the amount of the sealing member covering the upper surface of the semiconductor light-emitting element and the protective element. As a result, the stress applied to the sealing member due to the difference in the material between the sealing member and the frame body can be reduced to suppress the occurrence of exfoliation and cracks of the sealing member, and the reliability of the semiconductor light-emitting apparatus can be improved.

The fourth aspect of the present disclosure relates to the semiconductor light-emitting apparatus according to the first aspect, further including: a protective element bonded on the package substrate and covered by the sealing member, wherein a distance from the protective element to the frame body is smaller than the width of the upper surface of the frame body, and wherein a distance from the semiconductor light-emitting element to the protective element is smaller than the width of the upper surface of the frame body. According to the fourth aspect, the amount of the sealing member provided lateral to the protective element can be reduced by reducing the distance from the protective element to the frame body and reducing the distance from the semiconductor light-emitting element to the protective element. As a result, the stress applied to the sealing member due to the difference in the material between the sealing member and the frame body can be reduced, and the occurrence of exfoliation and cracks of the sealing member can be suppressed.

The fifth aspect of the present disclosure relates to the semiconductor light-emitting apparatus according to any one of the first to fourth aspects, wherein a gap is provided between the package substrate and the sealing member. According to the fifth aspect, the sealing member is provided in isolation from the package substrate so that the stress applied to the sealing member due to the difference in the material between the package substrate and the sealing member can be reduced. As a result, the occurrence of exfoliation and cracks of the sealing member can be suppressed, and the reliability of the semiconductor light-emitting apparatus can be improved.

The sixth aspect of the present disclosure relates to the semiconductor light-emitting apparatus according to any one of the first to fifth aspects, wherein a distance from each of the plurality of corner portions to the frame body is equal to or more than 10 μm and equal to or less than 300 μm. According to the fifth aspect, the occurrence of exfoliation and cracks of the sealing member can be suppressed, and the reliability of the semiconductor light-emitting apparatus can be improved by configuring the distance from the semiconductor light-emitting element to the frame body to be equal to or more than 10 μm and equal to or less than 300 μm.

The seventh aspect of the present disclosure relates to the semiconductor light-emitting apparatus according to any one of the first to sixth aspects, wherein the sealing member has a dome shape that is convex upward. According to the seventh aspect, the dome shape of the sealing member improves the light extraction efficiency of the semiconductor light-emitting apparatus.

What is claimed is:

1. A semiconductor light-emitting apparatus comprising:
a package substrate;
a semiconductor light-emitting element flip-chip bonded on the package substrate;
a frame body provided around the semiconductor light-emitting element on the package substrate; and
a sealing member that covers an upper surface of the semiconductor light-emitting element on the package substrate, covers an upper surface of the frame body, and has translucency at an emission wavelength of the semiconductor light-emitting element,
wherein the upper surface of the semiconductor light-emitting element has a plurality of corner portions, and a distance from each of the plurality of corner portions to the frame body is smaller than a width of the upper surface of the frame body.

2. The semiconductor light-emitting apparatus according to claim 1,
wherein, in a plan view of the upper surface of the semiconductor light-emitting apparatus, an area occupying a space inward of the frame body is equal to or less than twice an area occupying the upper surface of the semiconductor light-emitting element.

3. The semiconductor light-emitting apparatus according to claim 1, further comprising:
a protective element bonded on the package substrate and covered by the sealing member,
wherein, in a plan view of the upper surface of the semiconductor light-emitting apparatus, an area occupying a space inward of the frame body is equal to or less than twice a total area of the upper surface of the semiconductor light-emitting element and an upper surface of the protective element.

4. The semiconductor light-emitting apparatus according to claim 1, further comprising:
a protective element bonded on the package substrate and covered by the sealing member,
wherein a distance from the protective element to the frame body is smaller than the width of the upper surface of the frame body, and
wherein a distance from the semiconductor light-emitting element to the protective element is smaller than the width of the upper surface of the frame body.

5. The semiconductor light-emitting apparatus according to claim 1,
wherein a gap is provided between the package substrate and the sealing member.

6. The semiconductor light-emitting apparatus according to claim 1,
wherein a distance from each of the plurality of corner portions to the frame body is equal to or more than 10 μm and equal to or less than 300 μm.

7. The semiconductor light-emitting apparatus according to claim 1,
wherein the sealing member has a dome shape that is convex upward.
